(19) United States
(12) Patent Application Publication
(10) Pub. No.: US 2026/0338871 A1
(43) Pub. Date: Oct. 29, 2026

(54) METHOD AND SYSTEM FOR DETERMINING REUSABILITY OF A BATTERY

(71) Applicants: AUTOCRAFT SOLUTIONS GROUP LIMITED, Belton (GB); COVENTRY UNIVERSITY, Coventry (GB)

(72) Inventors: Zachary ELLIOTT, Loughborough (GB); Oliver CURNICK, Sutton Coldfield (GB); Simon WARBURTON, Belton (GB)

(73) Assignees: AUTOCRAFT SOLUTIONS GROUP LIMITED, Belton, KC (GB); COVENTRY UNIVERSITY, Coventry, WM (GB)

(21) Appl. No.: 19/124,372

(22) PCT Filed: Oct. 23, 2023
(86) PCT No.: PCT/GB2023/052772

§ 371 Date: Apr. 25, 2025

(30) Foreign Application Priority Data
Oct. 25, 2022 (GB) 2215774.7

(51) Int. Cl. G01R 31/392; B60L 3/00; G01R 31/367; G01R 31/378; G01R 31/388; G01R 31/389; G01R 31/396; H01M 10/54

(52) U.S. Cl. CPC G01R 31/392; G01R 31/367; G01R 31/378; G01R 31/388; G01R 31/389; G01R 31/396; H01M 10/54; B60L 3/0046

(57) ABSTRACT

A method of determining reusability of a battery includes conducting one or more safety diagnostic tests on the battery. The method includes measuring an open circuit voltage for each of a plurality of cells in the battery to determine a state of charge of the battery and performing an electrochemical dynamic response test on the battery to derive impedance and lithium transport parameters for each of the cells. The derived impedance and lithium transport parameters are analysed to identify one or more outlier cells in the battery and conducting one or more AC tests on the identified outlier cells to predict a degradation pathway for the cells over the lifetime of the battery. The method includes designating the outlier cells for reuse in a second application or for recycling based on the predicted degradation pathway. The disclosed method is efficient, accurate, and flexible for deter-mining reusability of battery.

### TECHNICAL FIELD

The present disclosure relates generally to the field of electric vehicles and battery testing; and more specifically, to a method and a system of determining reusability of a battery (e.g., an electric vehicle battery pack).

### BACKGROUND

With a rapid increase in the use of electric vehicles, the demand for high-performance energy storage systems (e.g., a battery or a battery pack) has increased immensely. It is well known that understanding the phenomena and functionality of various components inside a battery is required to promote the battery performance. Generally, a number of electric vehicle (EV) batteries are manufactured, processed, and tested at an electric vehicle service station, for use in electric vehicles, hybrid electric vehicles, plug-in hybrid electric vehicles, and the like. However, the testing is mostly limited to prototype testing or testing of newly manufactured batteries. In certain scenarios, for example, after prolonged use, some EV batteries may develop various kinds of defects and may not function properly. In such scenarios, a technical challenge associated with the uptake of EV batteries is how to manage the EV batteries when they are removed from an electric vehicle either because of a fault or because the EV batteries have reached the end of their usable life. The aforementioned technical challenge associated with the used or defective EV batteries can be addressed either on a small scale or on a large scale, depending on an application scenario.

In a typical battery testing method, same tests are carried out on each battery pack or battery module or cell (i.e., components of the battery), which is a tardy process. In conventional battery testing methods, it is typically required that each battery pack or battery module or cell needs to be pre-conditioned prior to testing which significantly adds to the testing time and makes the testing method complex in nature. Thus, there exists a technical problem of how to determine reusability of EV batteries (e.g., a used EV battery) accurately on an industrial scale.

Therefore, in light of the foregoing discussion, there exists a need to overcome the aforementioned drawbacks associated with the conventional methods of determining reusability of EV batteries

### SUMMARY

The present disclosure provides a method and a system of determining reusability of a battery. The present disclosure provides a solution to the existing problem of how to develop a holistic testing process that is efficient and reliable in determining reusability of EV batteries (e.g., a used EV battery). An aim of the present disclosure is to provide a solution that overcomes at least partially the problems encountered in prior art and provides an improved method and an improved system of determining reusability of a battery.

One or more objects of the present disclosure is achieved by the solutions provided in the enclosed independent claims. Advantageous implementations of the present disclosure are further defined in the dependent claims.

According to an aspect of the present disclosure, there is provided a method of determining reusability of a battery comprising conducting one or more safety diagnostic tests on the battery. The method further comprises measuring an Open Circuit Voltage (OCV) for each of a plurality of cells in the battery to determine a state of charge of the battery and performing an Electrochemical Dynamic Response (EDR) test on the battery to derive impedance and lithium transport parameters for each of the cells. The method further comprises analysing the derived impedance and lithium transport parameters to identify one or more outlier cells in the battery and conducting one or more AC tests on the identified outlier cells to predict a degradation pathway for the cells over the lifetime of the battery. The method further comprises designating the outlier cells for reuse in a second application or for recycling based on the predicted degradation pathway.

The disclosed method is flexible and universal in use (i.e., suitable to perform tests on all types of used EV batteries irrespective of their manufacturers or product type). The disclosed method is a comprehensive test process to evaluate the remaining usable life of the battery after a prolonged use in an electric vehicle. The method includes conducting one or more tests on the battery to decide whether one or more cells of the plurality of cells of the battery are replaced with healthy cells or the one or more cells of the plurality of cells are suitable for reuse in the second application or the one or more cells of the plurality of cells are recycled. Moreover, the decision about the suitability of the battery can be made by subjecting one or more damaged cells to deeper tests instead of subjecting the battery (i.e., the whole battery) to all tests. This results in time optimization, and maximisation of production throughput with improved efficiency and reliability. For example, the steps of EDR test on the battery to derive impedance and lithium transport parameters for each of the cells, analysing the derived impedance and lithium transport parameters to identify one or more outlier cells in the battery and conducting one or more AC tests on the identified outlier cells to predict a degradation pathway for the cells over the lifetime of the battery, as a whole provides a technical effect of improved accuracy while surprisingly reducing the time to identify the outlier cells for reuse in a second application or for recycling. Conventional methods are mostly not designed or meant to test a used battery. The testing of used batteries requires laboratory setup and pre-conditioning (e.g., chemical treatment of battery, etc. before testing) which is very time intensive and not practical for high volume testing.

In an implementation form, the method further comprises determining whether the OCV for each of the plurality of cells in the battery is below a pre-defined threshold voltage.

By virtue of determining whether the OCV for each of the plurality of cells in the battery is below the pre-defined threshold voltage, one or more cells are identified with high self-discharge rate.

In a further implementation form, the method further comprises identifying one or more damaged cells in the battery for replacement when the determined OCV is less than the pre-defined threshold voltage for the one or more damaged cells.

The replacement of the one or more damaged cells in the battery results in an enhanced life of the battery.

In a further implementation form, the EDR test on the battery is further configured to derive a state of health of Direct Current (DC) discharge data of the battery based on at least one of: a correlation between capacity and temperature of the battery or a correlation between the capacity and voltage of the battery.

The derivation of the state of health of DC discharge data of the battery leads to a reliable measurement of capacity fade, if any, of the battery.

In a further implementation form, the method further comprises analysing the derived state of health to identify the one or more outlier cells in the battery.

The identification of the one or more outlier cells in the battery leads to an accurate measurement of usable life of the battery.

In a further implementation form, the method further comprises comparing data from the derived state of health with a model dataset, having a plurality of predefined test values, of the battery to further evaluate the outlier cells of the battery.

The comparison of the derived state of health of the battery with the model dataset having the plurality of predefined test values results in an accurate prediction of the remaining age and a specific usage type of the battery.

In a further implementation form, the one or more AC tests on the identified outlier cells are conducted either in-situ within the battery or ex-situ by removing the identified outlier cells from the battery.

In a further implementation form, the one or more AC tests are conducted on the identified outlier cells at different amplitudes and different frequencies.

Performing the one or more AC tests on the identified outlier cells at different amplitudes (e.g., low and high amplitude) and different frequencies results in determination of whether the identified outlier cells are reusable or removable or recyclable.

In a further implementation form, the outlier cells are designated for reuse in the second application when the degradation pathway for the cells over the lifetime of the battery is predicted to be favourable for the reuse in the second application.

In a further implementation form, the outlier cells are designated for recycling when the degradation pathway for the cells over the lifetime of the battery is predicted to be unfavourable for reuse.

In a further implementation form, the identified outlier cells are removed from the battery and replaced with cells having substantially similar impedance and state of health as that of healthy cells remaining in the battery.

The removal and replacement of the identified outlier cells with the healthy cells increases the battery life by increasing the capacity and power that is supplied to a load connected to the battery.

In another aspect, the present disclosure provides a system of determining reusability of a battery. The system comprises a control circuit communicatively coupled to a plurality of test equipment, wherein the control circuit causes one or more of the plurality of test equipment to conduct one or more safety diagnostic tests on the battery. The control circuit further causes one or more of the plurality of test equipment to measure an Open Circuit Voltage (OCV) for each of a plurality of cells in the battery to determine a state of charge of the battery and perform an Electrochemical Dynamic Response (EDR) test on the battery to derive impedance and lithium transport parameters for each of the cells. The control circuit further causes one or more of the plurality of test equipment to analyse the derived impedance and lithium transport parameters to identify one or more outlier cells in the battery and conduct one or more AC tests on the identified outlier cells to predict a degradation pathway for the cells over the lifetime of the battery and designate the outlier cells for reuse in a second application or for recycling based on the predicted degradation pathway.

The system achieves all the advantages and technical effects of the method after execution of the method.

It is to be appreciated that all the aforementioned implementation forms can be combined. It has to be noted that all devices, elements, circuitry, units and means described in the present application could be implemented in the software or hardware elements or any kind of combination thereof. All steps which are performed by the various entities described in the present application as well as the functionalities described to be performed by the various entities are intended to mean that the respective entity is adapted to or configured to perform the respective steps and functionalities. Even if, in the following description of specific embodiments, a specific functionality or step to be performed by external entities is not reflected in the description of a specific detailed element of that entity which performs that specific step or functionality, it should be clear for a skilled person that these methods and functionalities can be implemented in respective software or hardware elements, or any kind of combination thereof. It will be appreciated that features of the present disclosure are susceptible to being combined in various combinations without departing from the scope of the present disclosure as defined by the appended claims.

Additional aspects, advantages, features and objects of the present disclosure would be made apparent from the drawings and the detailed description of the illustrative implementations construed in conjunction with the appended claims that follow.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those skilled in the art will understand that the drawings are not to scale. Wherever possible, like elements have been indicated by identical numbers.

Embodiments of the present disclosure will now be described, by way of example only, with reference to the following diagrams wherein:

FIG. 1 is a flowchart of a method of determining reusability of a battery, in accordance with an embodiment of the present disclosure;

FIGS. 2A and 2B collectively, is a flowchart that depicts a series of tests to be conducted on a battery for evaluation of specific battery parameters, in accordance with an embodiment of the present disclosure;

FIG. 3 is a diagram illustrating a system of determining reusability of a battery, in accordance with an embodiment of the present disclosure; and

FIG. 4 is an exemplary illustration depicting performing one or more tests and identification of one or more outlier cells in a battery, in accordance with an embodiment of the present disclosure.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practising the present disclosure are also possible.

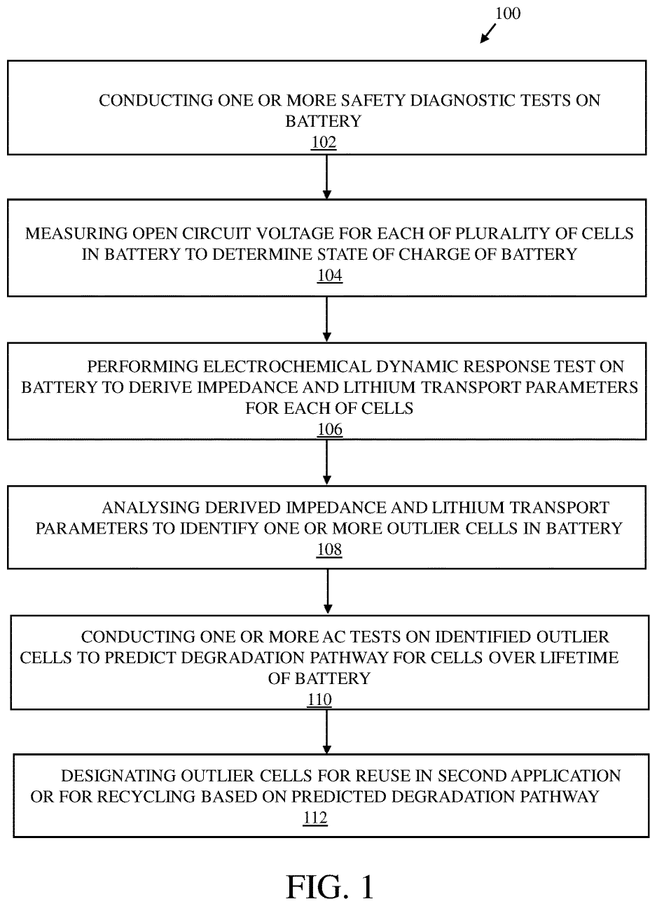

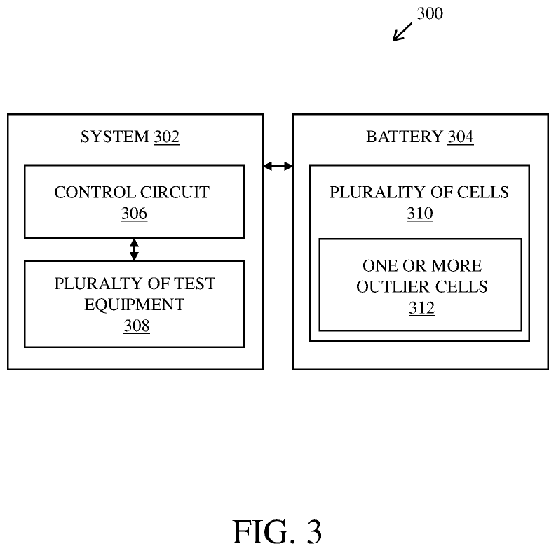

FIG. 1 is a flowchart of a method of determining reusability of a battery, in accordance with an embodiment of the present disclosure. With reference to FIG. 1, there is shown a method 100 that includes steps 102 to 112. The method 100 is executed by a system, described in detail, for example, in FIG. 3.

There is provided the method 100 of determining reusability of a battery. The battery refers to an electric vehicle (EV) battery pack, and the “battery” comprises cells or modules that are a group of cells within a battery pack. The battery may be used in the EV for long time therefore, the battery is removed from the EV either because of a fault or because the battery has reached the end of its usable life. In order to determine the fault and the reusability of the battery, the method 100 is used. In an implementation, the battery may include a number of cells, or battery modules or battery packs, or a combination thereof. The method 100 is a comprehensive test process used to ensure that EV batteries are processed quickly and screened reliably by focusing on finding the number of cells or battery modules or battery packs with specific types of damage(s) and use case. The method 100 can evaluate the future value and reliability of the number of cells or battery modules of the battery. Additionally, the method 100 can also be used for determining the power fade, capacity fade and degradation pathways of the battery with improved accuracy.

At step 102, the method 100 comprises conducting one or more safety diagnostic tests on the battery. Initially, the one or more safety diagnostic tests (e.g., high voltage, safety checks) are conducted on the battery. The one or more safety diagnostic tests may include, but are not limited to, connection of the battery to a ground wire, covering high voltage areas, sharing an awareness of any danger, paying attention to electric charge in cables, not touching high voltage areas with bare hands, use of gloves, and the like.

At step 104, the method 100 further comprises measuring an Open Circuit Voltage (OCV) for each of a plurality of cells in the battery to determine a state of charge of the battery. After conducting the safety diagnostic tests on the battery, the OCV of each of the plurality of cells of the battery is measured to identify the electrical potential capability of the battery (e.g., a rechargeable battery). Generally, the OCV is defined as a difference of electric potential between a positive and a negative terminal. While determining the OCV, any external load connected to the battery is removed.

In an implementation, the method 100 further comprises determining whether the OCV for each of the plurality of cells in the battery is below a pre-defined threshold voltage. The measured OCV of each of the plurality of cells of the battery is analysed to determine which cells from the plurality of cells have the OCV below the pre-defined threshold voltage.

In an implementation, the method 100 further comprises identifying one or more damaged cells in the battery for replacement when the determined OCV is less than the pre-defined threshold voltage for the one or more damaged cells. In a scenario of identification of the one or more damaged cells having the OCV less than the pre-defined threshold voltage, the one or more damaged cells are replaced with cells having similar characteristics such as, voltage and current requirements, with those cells having the OCV greater than the pre-defined threshold voltage.

At step 106, the method 100 further comprises performing an Electrochemical Dynamic Response (EDR) test on the battery to derive impedance and lithium transport parameters for each of the cells. After measuring the OCV of each of the plurality of cells of the battery, the EDR test is conducted on each of the plurality of cells of the battery. Generally, the EDR test is conducted to measure the flow of ions between positive and negative terminals of the battery. In an implementation, the EDR test may be carried out on each of the plurality of cells of the battery while logging cell voltages which are measured either directly from the plurality of cells or by reading from a battery management system (BMS). The EDR test has a low impact on the temperature of the battery and therefore, the EDR test can be preceded by other tests. The EDR test provides the information about the impedance (e.g., ohmic resistance) and lithium transport parameters of each of the cells of the battery.

At step 108, the method 100 further comprises analysing the derived impedance and lithium transport parameters to identify one or more outlier cells in the battery. The derived impedance and lithium transport parameters of each of the plurality of cells of the battery are analysed to identify the one or more outlier cells with high impedance and low capacity. Low capacity means a reduction in the usable capacity of the battery. The one or more outlier cells are subjected to further tests for detailed analysis of their state of health (SoH). Depending on the SoH of the one or more outlier cells, the one or more outlier cells are either repaired or replaced with other cells having similar characteristics.

In an implementation, the EDR test on the battery is further configured to derive a state of health of Direct Current (DC) discharge data of the battery based on at least one of: a correlation between capacity and temperature of the battery or a correlation between the capacity and voltage of the battery. The EDR test is further used to analyse the DC capacity of the battery. For analysis of the DC capacity, the battery is charged and then discharged either fully or partially, with all the cell voltages logged in. The charging/discharging of the battery provides the measurement of the capacity figure for each of the plurality of cells of the battery. The capacity figure of the battery can also be obtained by analysis of variation in the capacity (i.e., charge) by varying the voltages (i.e., dQ/dV) and analysis of variation in the capacity (i.e., charge) by varying the temperature of the battery (i.e., dQ/dT).

In an implementation, the EDR test may include Coulomb counting, current pulse counting and measurement of AC impedance at 1 kHz. The Coulomb counting refers to a reduced capacity of the battery and the current pulse counting refers to a reduced power output of the battery.

In an implementation scenario, if the battery supplies a high percentage of charge energy in the discharge phase, it is determined that the battery has a good capacity, which can be expressed as a percentage of the plurality of cells of the battery as a new capacity rating. For example, a battery can be charged to 100% state of charge (SoC) and then, discharged to its minimum level, the total amount of energy discharged can be compared against the plurality of cells of the battery as the new capacity according to equation (1).

$$SoH = \frac{energy discahrged ( kWh )}{as new capacity ( kWh )} \times 100$$

In an implementation, the method 100 further comprises analysing the derived state of health to identify the one or more outlier cells in the battery. The equation (1) is used to determine the state of health of the one or more outlier cells in the battery with more reliability.

In an implementation, the method 100 further comprises comparing data from the derived state of health with a model dataset, having a plurality of predefined test values, of the battery to further evaluate the outlier cells of the battery. The derived state of health of DC discharge data of the battery and the state of health of the one or more outlier cells are compared with the model dataset, having the plurality of predefined test values, of the battery to identify whether the derived parameters are unusual with respect to a given battery type, an age of the battery, or a battery usage parameter.

In an implementation, if voltages of the plurality of cells of the battery during the DC discharge data analysis have a delta of less than a required milli-Volt (mV) figure then, the plurality of cells of the battery can be assumed as healthy cells.

At step 110, the method 100 further comprises conducting one or more AC tests on the identified outlier cells to predict a degradation pathway for the cells over the lifetime of the battery. In a case, if analysis of the EDR test and the DC discharge data identifies one or more cells from the plurality of cells of the battery which perform unsatisfactorily (i.e., the one or more outlier cells) then, part of battery containing the one or more cells whose performance is unsatisfactory, is separately subjected to the one or more AC tests instead of subjecting the battery (i.e., the whole battery) for further testing. In an implementation, an individual cell or a battery module may also be subjected to the one or more AC tests. The one or more AC tests are conducted to determine a root cause of failure of the one or more outlier cells. Moreover, the one or more AC tests are conducted to determine the degradation pathway for the one or more outlier cells. The degradation pathway includes formation of solid electrolyte interphase (SEI) layer, particle fracture, lithium plating and dendrite growth, structural disordering, graphite exfoliation, pore blockage, and the like. The aforementioned degradation pathways are generally considered to be the cause of the battery degradation during normal operation of the battery. The degradation pathway varies with change in the temperature, current and SoC of the battery.

In an implementation, the one or more AC tests on the identified outlier cells are conducted either in-situ within the battery or ex-situ by removing the identified outlier cells from the battery. In an implementation, the one or more AC tests are conducted on the identified outlier cells lying within the battery (i.e., in-situ). In another implementation, the one or more AC tests are conducted on the identified outlier cells after removing them from the battery (i.e., ex-situ).

In an implementation, the one or more AC tests are conducted on the identified outlier cells at different amplitudes and different frequencies. The testing data obtained after conducting the one or more AC tests can be interpreted by use of either curve fitting, or an equivalent circuit model or analysis of distribution of relaxation times (DRT). Furthermore, the one or more AC tests conducted on the identified outlier cells includes analysing harmonics of AC data in which an amplitude is greater than a pre-defined threshold value (i.e., high amplitude AC data), analysing the DRT of the AC data in which the amplitude is less than the defined threshold, or deriving an equivalent circuit fitting of the AC data in which the amplitude is less than the defined threshold (i.e., low amplitude AC data). Moreover, a few tests namely, electrochemical impedance spectroscopy (EIS), DRT and non-linear frequency response analysis (NFRA) tests may be conducted on the identified outlier cells to identify presence and severity of lithium plating. The EIS and DRT tests data may be used to distinguish the relative contributions of calendar and cycle ageing to impedance growth and capacity fade. Each of the EIS, DRT and NFRA tests is highly affected by temperature and SoC of the battery therefore, it is required to measure the temperature and OCV of each cell and correct for the effects of these noise factors.

At step 112, the method 100 further comprises designating the outlier cells for reuse in a second application or for recycling based on the predicted degradation pathway. The testing data obtained by conducting the one or more AC tests on the identified outlier cells is used to decide whether the outlier cells are suitable for reuse in the second application or discard the outlier cells for recycling, based on the predicted degradation pathway.

In an implementation, the outlier cells are designated for reuse in the second application when the degradation pathway for the cells over the lifetime of the battery is predicted to be favourable for the reuse in the second application. Based on the one or more AC tests conducted on the outlier cells, the outlier cells can be selected for reuse in the second application if the degradation pathway for each of the plurality of cells of the battery is favourable for reuse on the second application, for the remaining lifetime of the battery. The outlier cells selected for reuse in the second application may be sent to a remanufacturing inventory.

In an implementation, the outlier cells are designated for recycling when the degradation pathway for the cells over the lifetime of the battery is predicted to be unfavourable for reuse. Based on the one or more AC tests conducted on the outlier cells, the outlier cells can be selected for recycling if the degradation pathway for each of the plurality of cells of the battery is unfavourable for reuse.

In an implementation, the identified outlier cells are removed from the battery and replaced with cells having substantially similar impedance and state of health as that of healthy cells remaining in the battery. The outlier cells which are removed from the battery and do not indicate the unfavourable degradation pathway can be replaced with the cells having substantially similar (e.g., ±20% difference in impedance and state of health) impedance and state of health as that of healthy cells remaining in the battery. In an implementation, the similar characteristics may include capacity characteristics of those cells remaining in the battery, after adjusting the state of charge of the replaced cells, if required. After reassembling the cells in the battery, the battery can be subjected to a standard end of line testing.

Thus, the method 100 is a time-optimised and a comprehensive test process to find any future value left in the battery and to decide whether one or more cells of the plurality of cells of the battery are replaced with healthy cells or the one or more cells of the plurality of cells are suitable for reuse in the second application or the one or more cells of the plurality of cells are recycled. In the method 100, a series of tests including the EDR test, the DC discharge data test and the one or more AC tests are conducted on the battery. Moreover, in the method 100, the one or more cells of the plurality of cells of the battery failing the EDR test are subjected to the DC discharge data test and the part of battery comprising the one or more cells failing the DC discharge data test is subjected to the one or more AC tests to find the degradation pathway. In this way, the decision about the suitability of plurality of cells of the battery can be made by subjecting only a portion of the battery to deeper tests instead of subjecting the battery to all tests. Therefore, the method 100 results in maximising the production throughput with improved efficiency and reliability.

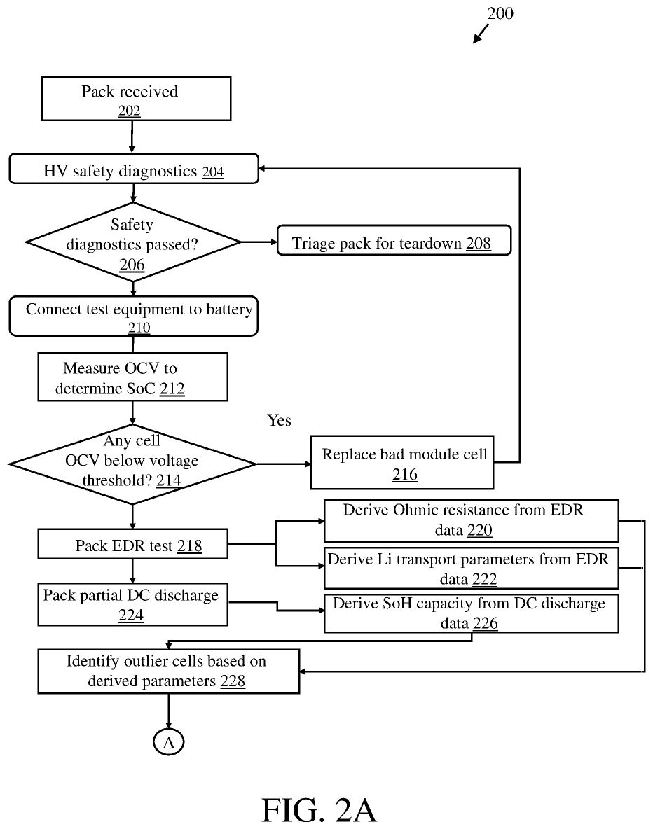

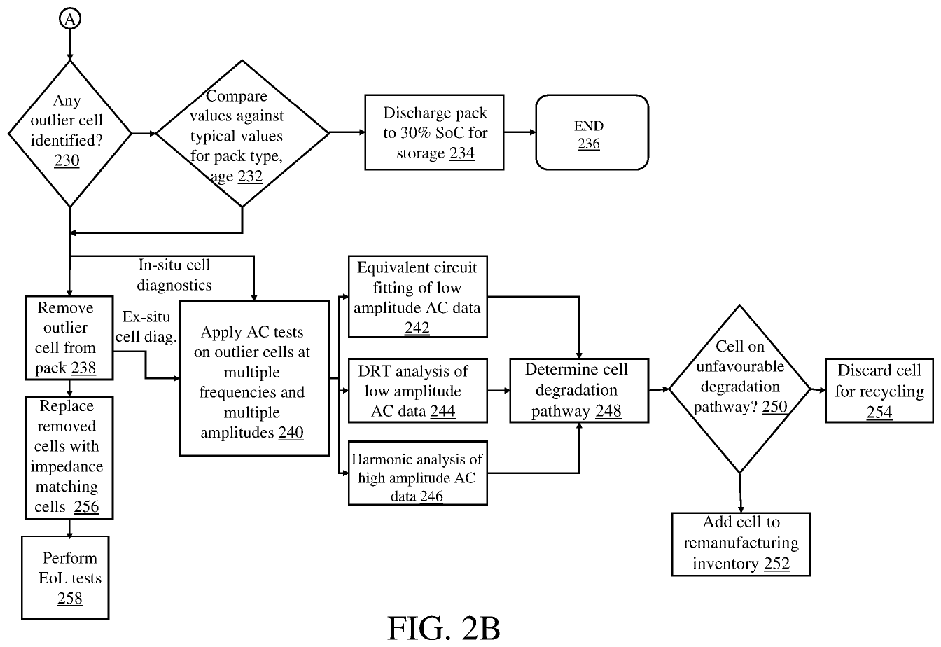

FIGS. 2A and 2B collectively, is a flowchart that depicts a series of tests to be conducted on a battery for evaluation of specific battery parameters, in accordance with an embodiment of the present disclosure. FIGS. 2A and 2B are described in conjunction with elements from FIG. 1. With reference to FIGS. 2A and 2B, there is shown a flowchart 200 that includes operations 202 to 258. The operations 202 to 228 are shown in FIG. 2A and the operations 230 to 258 are shown in FIG. 2B.

Referring to FIG. 2A, at operation 202, a battery is received at a battery servicing facility (e.g., an electric vehicle service station).

At operation 204, high voltage (HV) safety diagnostic tests are conducted on the battery.

At operation 206, this is checked that whether the battery passes the safety diagnostic tests or not. If the battery passes the safety diagnostic tests, then, operation 210 is executed else, an operation 208 is executed.

At operation 208, the battery is subjected for teardown.

At operation 210, a test equipment is connected to the battery.

At operation 212, the OCV for each of a plurality of cells of the battery is measured to determine a state of charge (SoC) of the battery.

At operation 214, this is checked that whether one or more cells from the plurality of cells of the battery has the measured OCV less than a pre-defined threshold voltage. If the one or more cells from the plurality of cells of the battery has the measured OCV less than the pre-defined threshold voltage then, an operation 216 is executed else, an operation 218 is executed.

At operation 216, the one or more cells having the measured OCV less than the pre-defined threshold voltage are replaced by healthy cells and the operations from 204 to 214 are executed again on the battery.

At operation 218, the one or more cells from the plurality of cells of the battery are subjected to the EDR test.

At operation 220, from the EDR testing data, impedance (i.e., ohmic resistance) for each of the cells of the battery is derived.

At operation 222, from the EDR testing data, lithium transport parameters for each of the cells of the battery are derived.

At operation 224, the battery is further subjected to the partial DC discharge data.

At operation 226, from the partial DC discharge data, a state of health of the battery is derived by dQ/dV analysis (i.e., analysis of change in charge by varying the voltage).

At operation 228, the derived impedance, lithium transport parameters and the state of health of the battery are used to identify the one or more outlier cells of the battery.

Now referring to FIG. 2B, at operation 230, it is checked whether any outlier cell is identified or not. If one or more outlier cells are identified then, an operation 232 is executed.

At operation 232, the derived state of health of the battery is compared with a model dataset having a plurality of predefined test values, of the battery to further evaluate the outlier cells of the battery.

At operation 234, if the compared values seem ok then, the battery is discharged to 30% SoC and stored for future use.

At operation 236, the control of the flowchart 200 moves to an end.

At operation 238, the identified one or more outlier cells are removed from the battery and subjected to one or more AC tests at operation 240. In another implementation, the identified one or more outlier cells are not required to be removed from the battery and the one or more AC tests can be conducted on the identified outlier cells lying inside the battery.

At operation 240, the one or more AC tests are conducted on the identified outlier cells at multiple amplitudes (e.g., C/20 to 3 C) and multiple frequencies (e.g., 10 kHz-0.05 Hz).

At operation 242, the one or more AC tests can be conducted on the identified outlier cells by use of an equivalent circuit fitting of the AC data in which the amplitude is less than a defined threshold value.

At operation 244, the one or more AC tests can be conducted on the identified outlier cells by analysing a distribution of relaxation times (DRT) of the AC data in which the amplitude is less than the defined threshold value.

At operation 246, the one or more AC tests can be conducted on the identified outlier cells by analysing harmonics of high amplitude AC data.

At operation 248, by conducting the one or more AC tests, the outlier cells are designated for reuse in a second application or for recycling based on a predicted degradation pathway.

At operation 250, it is checked if any outlier cell is on an unfavourable degradation pathway. If there exists any outlier cell on the unfavourable degradation pathway then, an operation 252 is executed else, an operation 254 is executed.

At operation 252, the outlier cell on the unfavourable degradation pathway is discarded for recycling. In an implementation, if any outlier cell is found on the unfavourable degradation pathway, then rest of the cells of the battery can be assumed to be on the similar pathway. Therefore, if possible, each of the plurality of the cells of the battery are discarded for recycling.

At operation 254, if there does not exist any outlier cells with the unfavourable degradation pathway, then the identified outlier cells can be reused in the second application. Therefore, the identified outlier cells are sent to the remanufacturing inventory.

At operation 256, the identified one or more outlier cells are removed from the battery and replaced with cells having similar impedance (e.g., ±20% difference of impedance) and state of health as that of healthy cells remaining in the battery.

At operation 258, the battery is subjected to a standard end of line testing.

FIG. 3 illustrates a system of determining reusability of a battery, in accordance with an embodiment of the present disclosure. FIG. 3 is described in conjunction with elements from FIGS. 1 and 2. With reference to FIG. 3, there is shown a block diagram 300 of a system 302. The system 302 is used for determining reusability of a battery 304. The system 302 comprises a control circuit 306 communicatively coupled to a plurality of test equipment 308. Furthermore, the battery 304 comprises a plurality of cells 310 which includes one or more outlier cells 312. The control circuit 306 of the system 302 is configured to execute the method 100 (of FIG. 1).

The system 302 may include suitable logic, circuitry, interfaces, or code that is configured for determining reusability of the battery 304. The system 302 may be either automatic or semi-automatic in nature. The system 302 may be used at an electric vehicle service station. Moreover, the system 302 uses a comprehensive approach (i.e., the method 100) in order to process the battery 304 quickly and to determine whether the battery 304 is reusable or not with reliability.

The control circuit 306 may include suitable logic, circuitry, interfaces, or code that is configured to control the plurality of test equipment 308 to conduct various tests on each of the plurality of cells 310 of the battery 304. Examples of the control circuit 306 may include, but are not limited to, a processor, a co-processor, a microprocessor, a microcontroller, a complex instruction set computing (CISC) processor, an application-specific integrated circuit (ASIC) processor, a reduced instruction set (RISC) processor, a very long instruction word (VLIW) processor, a central processing unit (CPU), a state machine, a data processing unit, and other processors or circuits. Moreover, the control circuit 306 may refer to one or more individual processors, processing devices, a processing unit that is part of a machine

There is provided the system 302 of determining reusability of the battery 304. The system 302 comprises the control circuit 306 communicatively coupled to the plurality of test equipment 308, wherein the control circuit 306 causes one or more of the plurality of test equipment 308 to conduct one or more safety diagnostic tests on the battery 304. Initially, each of the plurality of test equipment 308 is configured to conduct the one or more safety diagnostic tests on the battery 304. The safety diagnostic tests have been described in detail, for example, in FIG. 1.

The control circuit 306 further causes one or more of the plurality of test equipment 308 to measure an Open Circuit Voltage (OCV) for each of the plurality of cells 310 in the battery 304 to determine a state of charge of the battery 304. The OCV of each of the plurality of cells 310 of the battery 304 is measured to identify the electrical potential capability of the battery 304.

The control circuit 306 further causes one or more of the plurality of test equipment 308 to perform an Electrochemical Dynamic Response (EDR) test on the battery 304 to derive impedance and lithium transport parameters for each of the cells. After measuring the OCV of each of the plurality of cells 310 of the battery 304, the one or more of the plurality of test equipment 308 is configured to perform the EDR test on each of the plurality of cells 310 of the battery 304 to compute the impedance (e.g., ohmic resistance) and lithium transport (e.g., lithium plating) parameters of each of the cells.

The control circuit 306 further causes one or more of the plurality of test equipment 308 to analyse the derived impedance and lithium transport parameters to identify one or more outlier cells 312 in the battery 304. The derived impedance and lithium transport parameters of each of the plurality of cells 310 of the battery 304 are analysed to identify the one or more outlier cells 312 with high impedance and low capacity.

The control circuit 306 further causes one or more of the plurality of test equipment 308 to conduct one or more AC tests on the identified outlier cells to predict a degradation pathway for the cells over the lifetime of the battery 304. If analysis of the EDR test identifies one or more cells from the plurality of cells 310 of the battery 304 which perform unsatisfactorily (i.e., the one or more outlier cells 312) then, part of battery 304 containing the one or more outlier cells 312 whose performance is unsatisfactory, is separately subjected to the one or more AC tests. The one or more AC tests are conducted to determine whether the degradation pathway of the outlier cells is favourable or unfavourable for reuse.

The control circuit 306 further causes one or more of the plurality of test equipment 308 to designate the outlier cells for reuse in a second application or for recycling based on the predicted degradation pathway. The testing data obtained by conducting the one or more AC tests on the identified outlier cells is used to decide whether the outlier cells are suitable for reuse in the second application or discard the outlier cells for recycling, based on the predicted degradation pathway.

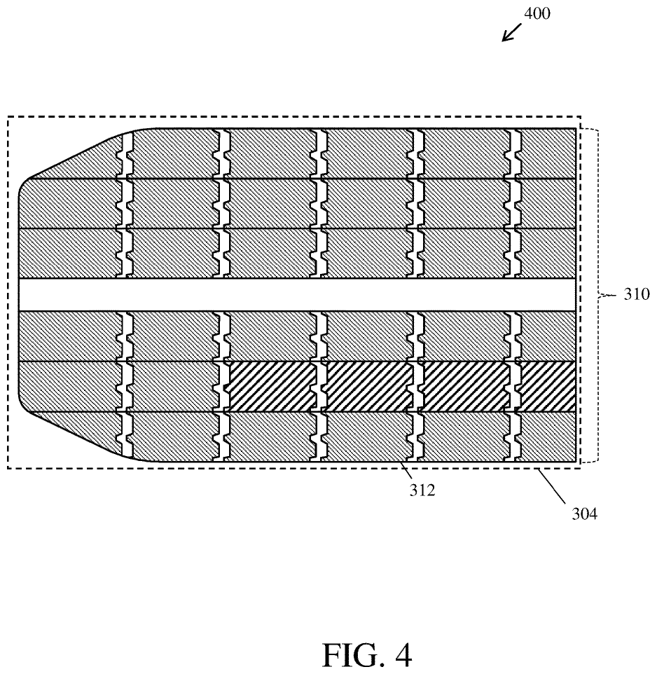

FIG. 4 is an exemplary illustration to perform one or more tests and to identify one or more outlier cells in a battery, in accordance with an embodiment of the present disclosure. FIG. 4 is described in conjunction with elements from FIGS. 1, 2A-2B and 3. With reference to FIG. 4, there is shown an exemplary illustration 400 that depicts performing one or more tests on the battery 304 (of FIG. 3) comprising the plurality of cells 310 in order to identify the one or more outlier cells 312 in the battery 304. The battery 304 is represented by a dashed box, which is used for illustration purposes only and does not form a part of circuitry.

The control circuit 306 of the system 302 causes the plurality of test equipment 308 to perform HV safety diagnostics tests on the battery 304. Thereafter, measuring the OCV of each of the plurality of cells 310 of the battery to determine the SoC of the battery 304. The plurality of test equipment 308 is further configured to perform the EDR test on the battery 304 to derive the impedance (i.e., ohmic resistance) and lithium transport parameters of each of the plurality of cells 310 of the battery 304. The derived impedance and lithium transport parameters are analysed to identify the one or more outlier cells 312 in the battery 304. The portion of the battery 304 comprising the identified one or more outlier cells 312 is subjected to the one or more AC tests instead of subjecting the complete battery (i.e., the battery 304) to the AC tests. Consecutively, time optimization and reliability are obtained while testing the battery 304. The one or more AC tests are conducted on the identified outlier cells to predict the degradation pathway and to decide which outlier cells are suitable for reuse in the second application and which one should be recycled based on the predicted degradation pathway.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural. The word “exemplary” is used herein to mean “serving as an example, instance or illustration”. Any embodiment described as “exemplary” is not necessarily to be construed as preferred or advantageous over other embodiments and/or to exclude the incorporation of features from other embodiments. The word “optionally” is used herein to mean “is provided in some embodiments and not provided in other embodiments”. It is appreciated that certain features of the present disclosure, which are, for clarity, described in the context of separate embodiments, may also be provided in combination in a single embodiment. Conversely, various features of the present disclosure, which are, for brevity, described in the context of a single embodiment, may also be provided separately or in any suitable combination or as suitable in any other described embodiment of the disclosure.

1. A method of determining reusability of a battery comprising:
conducting one or more safety diagnostic tests on the battery;
measuring an Open Circuit Voltage (OCV) for each of a plurality of cells in the battery to determine a state of charge of the battery;
performing an Electrochemical Dynamic Response (EDR) test on the battery to derive impedance and lithium transport parameters for each of the plurality of cells;
analysing the derived impedance and lithium transport parameters to identify one or more outlier cells in the battery;
conducting one or more AC tests on the identified outlier cells to predict a degradation pathway for the cells over a lifetime of the battery; and
designating the outlier cells for reuse in a second application or for recycling based on the predicted degradation pathway.

2. The method of claim 1, further comprising determining whether the OCV for each of the plurality of cells in the battery is below a pre-defined threshold voltage.

3. The method of claim 2, further comprising identifying one or more damaged cells in the battery for replacement when the determined OCV is less than the pre-defined threshold voltage for the one or more damaged cells.

4. The method according to of claim 1, wherein the EDR test on the battery is further configured to derive a state of health of Direct Current (DC) discharge data of the battery based on at least one of: a correlation between capacity and temperature of the battery or a correlation between the capacity and voltage of the battery.

5. The method of claim 4, further comprising analysing the derived state of health to identify the one or more outlier cells in the battery.

6. The method of claim 4, further comprising comparing data from the derived state of health with a model dataset, having a plurality of predefined test values, of the battery to further evaluate the outlier cells of the battery.

7. The method of claim 1, wherein the one or more AC tests on the identified outlier cells are conducted either in-situ within the battery or ex-situ by removing the identified outlier cells from the battery.

8. The method of claim 1, wherein the one or more AC tests are conducted on the identified outlier cells at different amplitudes and different frequencies.

9. The method of claim 1, wherein the outlier cells are designated for reuse in the second application when the degradation pathway for the cells over the lifetime of the battery is predicted to be favourable for the reuse in the second application.

10. The method of claim 1, wherein the outlier cells are designated for recycling when the degradation pathway for the cells over the lifetime of the battery is predicted to be unfavourable for reuse.

11. The method of claim 1, wherein the identified outlier cells are removed from the battery and replaced with cells having substantially similar impedance and state of health as that of healthy cells remaining in the battery.

12. A system of determining reusability of a battery, comprising:
a control circuit communicatively coupled to a plurality of test equipment, wherein the control circuit-causes one or more of the plurality of test equipment to:
conduct one or more safety diagnostic tests on the battery;
measure an Open Circuit Voltage (OVC) for each of a plurality of cells in the battery to determine a state of charge of the battery;
perform an Electrochemical Dynamic Response (EDR) test on the battery to derive impedance and lithium transport parameters for each of the cells;
analyse the derived impedance and lithium transport parameters to identify one or more outlier cells in the battery;
conduct one or more AC tests on the identified outlier cells to predict a degradation pathway for the cells over a lifetime of the battery; and
designate the outlier cells for reuse in a second application or for recycling based on the predicted degradation pathway.
